(19) United States
(12) Patent Application Publication
(10) Pub. No.: US 2017/0184985 A1
(43) Pub. Date: Jun. 29, 2017

(54) PHOTOCONDUCTOR HAVING CROSSLINKABLE TRANSPORT MOLECULES HAVING FOUR RADICAL POLYMERIZABLE GROUPS AND METHOD TO MAKE THE SAME

(71) Applicant: LEXMARK INTERNATIONAL, INC., LEXINGTON, KY (US)

(72) Inventors: DAVID GLENN BLACK, BROOMFIELD, CO (US); MARK THOMAS BELLINO, LOVELAND, CO (US); WEIMEI LUO, LOUISVILLE, CO (US)

(21) Appl. No.: 14/982,072

(22) Filed: Dec. 29, 2015

(51) Int. Cl. G03G 5/05; C23C 16/44

(52) U.S. Cl. CPC G03G 5/0525; C23C 16/44

(57) ABSTRACT

An improved organic photoconductor drum having a protective overcoat layer and method to make the same is provided. The protective overcoat layer is prepared from a curable composition including a crosslinkable hole transport molecule containing four radical polymerizable functional groups in combination with a crosslinkable acrylate having at least 6 functional groups.

### CROSS REFERENCES TO RELATED APPLICATIONS

None

### BACKGROUND

1. Field of the Disclosure

The present disclosure relates generally to electrophotographic image forming devices, more particularly to an organic photoconductor drum having a protective overcoat layer and method to make the same is provided. This photoconductor drum has improved mechanical wear resistance and excellent electrical properties. The overcoat layer contains a charge transport molecule having four radical polymerizable groups in combination with a crosslinkable acrylate having at least 6 functional groups.

2. Description of the Related Art

Organic photoconductor drums have generally replaced inorganic photoconductor drums in electrophotographic image forming device including copiers, facsimiles and laser printers due to their superior performance and numerous advantages compared to inorganic photoconductors. These advantages include improved optical properties such as having a wide range of light absorbing wavelengths, improved electrical properties such as having high sensitivity and stable chargeability, availability of materials, good manufacturability, low cost, and low toxicity.

While the above enumerated performance advantages exhibited by organic photoconductor drums are significant, inorganic photoconductor drums traditionally exhibit much higher durability—thereby resulting in a photoconductor having a desirable longer life. Inorganic photoconductor drums (e.g., amorphous silicon photoconductor drums) are ceramic-based, thus are extremely hard and abrasion resistant. In comparison, the surface of an organic photoconductor drum is typically comprised of a low molecular weight charge transport material, and an inert polymeric binder and are susceptible to scratches and abrasions. Therefore, the drawback of using organic photoconductor drums typically arises from mechanical abrasion of the surface layer of the photoconductor drum due to repeated use. Abrasion of the photoconductor drum surface may arise from its interaction with print media (e.g. paper), paper dust, or other components of the electrophotographic image forming device such as the cleaner blade or charge roll.

Moreover, the abrasion of the photoconductor drum surface degrades its electrical properties, such as sensitivity and charging properties. Electrical degradation results in poor image quality, such as lower optical image density, and background fouling. When a photoconductor drum is locally abraded, images often have dark toner bands due to the inability to hold charge in the thinner regions. This black banding on the print media often marks the end of the life of the photoconductor drum, thereby leaving the owner of the printer with no choice but to purchase another expensive photoconductor drum or image unit. The life of photoconductor drums is extremely variable. Unfortunately, prior art organic photoconductor drums can only print less than 100K pages before they have to be replaced.

Increasing the life of the photoconductor drum will allow the photoconductor drum to become a permanent part of the electrophotographic image forming device. In other words, the photoconductor drum will no longer be a replaceable unit nor be viewed as a consumable item that has to be purchased multiple times by the consumer. Photoconductor drums having an ‘ultra long life’ allow the printer to operate with a lower cost-per-page, more stable image quality, and less waste leading to a greater customer satisfaction with his or her printing experience. A photoconductor drum having an ultra long life can be defined as photoconductor drum having the ability to print at a minimum 250,000 pages before the consumer has to purchase a costly replacement drum.

An overcoat formulation comprising a radical polymerizable charge transport molecule in combination with hexafunctional urethane acrylates is disclosed in U.S. Pat. No. 8,940,466 entitled PHOTOCONDUCTOR OVERCOATS COMPRISING RADICAL POLYMERIZABLE CHARGE TRANSPORT MOLECULES AND HEXA FUNCTIONAL URETHANE ACRYLATES, which is assigned to the assignee of the present application and is incorporated by reference herein in its entirety. Prior art overcoat formulations do not impart onto the photoconductor drum the ability to print over 250,000 pages while simultaneously maintaining good electrical properties. Moreover, it is important that any suitable overcoat layer not significantly alter the electrophotographic properties of the photoconductor drum. If the overcoat layer is too electrically insulating, the photoconductor drum will not discharge and will result in a poor latent image. On the other hand, if the overcoat layer is too electrically conducting, the electrostatic latent image will spread, thereby resulting in a blurred image. These properties are obviously not desirable. Therefore a protective overcoat layer that extends the printing life of the photoconductor drum must also simultaneously allow charge migration to the photoconductor surface for development of the latent image with toner. Additionally, the present inventors have discovered that charge or ‘hole’ transport molecules in an overcoat must have radical polymerizable functionality if they are to be compatible with radical polymerizable binders that contain crosslinkable functionality found in an overcoat formulation.

### SUMMARY

The present disclosure provides an overcoat layer for an organic photoconductor drum of an electrophotographic image forming device to print over 250,000 pages while simultaneously maintaining good electrical properties. The overcoat layer is prepared from an ultraviolet (UV) curable composition including a crosslinkable urethane resin binder having at least six radical polymerizable functional groups and a crosslinkable hole transport molecule having four radical polymerizable functional groups. The general structure of the crosslinkable hole transport molecule of the present invention is exemplified below:

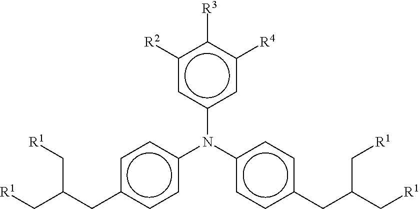

wherein R¹ is a radical polymerizable group, the groups R², R³, and R⁴ may be the same or different, and wherein each of R², R³, and R⁴ are independently selected from the group consisting of (i) hydrogen, (ii) an alkyl group, which can be linear or branched, saturated or unsaturated, cyclic or acyclic, substituted or unsubstituted alkyl, (iii) an aryl group, which can be substituted or unsubstituted aryl, (iv) an arylalkyl group, which can be substituted or unsubstituted arylalkyl, wherein the alkyl portion of the arylalkyl can be linear or branched, saturated or unsaturated, cyclic or acyclic, and substituted or unsubstituted, (v) an alkylaryl group, which can be substituted or unsubstituted alkylaryl, wherein the alkyl portion of the alkylaryl can be linear or branched, saturated or unsaturated, cyclic or acyclic, and substituted or unsubstituted, (vi) an alkoxy group, (vii) an aryloxy group, which can be substituted or unsubstituted aryloxy, (viii) an arylalkyloxy group, which can be substituted or unsubstituted arylalkyloxy, wherein the alkyl portion of the arylalkyloxy can be linear or branched, saturated or unsaturated, cyclic or acyclic, and substituted or unsubstituted, and (ix) an alkylaryloxy group, which can be substituted or unsubstituted alkylaryloxy, wherein the alkyl portion of the alkylaryloxy can be linear or branched, saturated or unsaturated, cyclic or acyclic, and substituted or unsubstituted. In one embodiment, the radical polymerizable group R¹ is an acrylate group, R² and R⁴ are hydrogen and R³ is a methyl group.

The amount of the crosslinkable urethane acrylate resin binder having at least six radical polymerizable functional groups in the curable overcoat composition is about 20 percent to about 80 percent by weight of the overcoat composition. The amount of the crosslinkable charge transport molecule having four radical polymerizable functional groups in the curable overcoat composition is about 20 percent to about 80 percent by weight of the overcoat composition. This overcoat layer of the present invention imparts onto the photoconductor drum the ability to print approximately 250,000 pages while simultaneously maintaining good electrical properties.

Also disclosed is a photoconductor drum having a support element, a charge generation layer disposed over the support element, a charge transport layer disposed over the charge generation layer, and an overcoat layer disposed over the charge transport layer comprising a curable composition including a crosslinkable hole transport molecule containing four radical polymerizable functional groups as exemplified below:

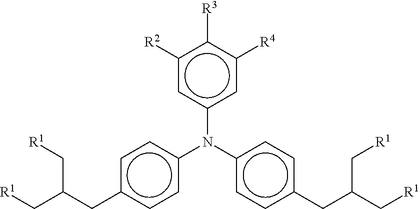

where R¹ is a radical polymerizable functional group is selected from the group consisting of acrylate group, methacrylate group, allylic group, glycidyl ether group and epoxy group. The groups R², R³, and R⁴ may be the same or different, and wherein each of R², R³, and R⁴ are independently selected from the group consisting of (i) hydrogen, (ii) an alkyl group, which can be linear or branched, saturated or unsaturated, cyclic or acyclic, substituted or unsubstituted alkyl, (iii) an aryl group, which can be substituted or unsubstituted aryl, (iv) an arylalkyl group, which can be substituted or unsubstituted arylalkyl, wherein the alkyl portion of the arylalkyl can be linear or branched, saturated or unsaturated, cyclic or acyclic, and substituted or unsubstituted, (v) an alkylaryl group, which can be substituted or unsubstituted alkylaryl, wherein the alkyl portion of the alkylaryl can be linear or branched, saturated or unsaturated, cyclic or acyclic, and substituted or unsubstituted, (vi) an alkoxy group, (vii) an aryloxy group, which can be substituted or unsubstituted aryloxy, (viii) an arylalkyloxy group, which can be substituted or unsubstituted arylalkyloxy, wherein the alkyl portion of the arylalkyloxy can be linear or branched, saturated or unsaturated, cyclic or acyclic, and substituted or unsubstituted, and (ix) an alkylaryloxy group, which can be substituted or unsubstituted alkylaryloxy, wherein the alkyl portion of the alkylaryloxy can be linear or branched, saturated or unsaturated, cyclic or acyclic, and substituted or unsubstituted. In one embodiment, the radical polymerizable group R¹ is an acrylate group, R² and R⁴ are hydrogen and R³ is a methyl group.

### BRIEF DESCRIPTION OF THE DRAWINGS

The accompanying drawings incorporated in and forming a part of the specification, illustrate several aspects of the present disclosure, and together with the description serve to explain the principles of the present disclosure.

FIG. 1 is a schematic view of an electrophotographic image forming device.

FIG. 2 is a cross-sectional view of a photoconductor drum of the electrophotographic image forming device.

FIG. 3 shows the photo induced discharge (PID) curves of a photoconductor drum having the overcoat of the present invention and a prior art photoconductor drum.

### DETAILED DESCRIPTION

It is to be understood that the disclosure is not limited in its application to the details of construction and the arrangement of components set forth in the following description or illustrated in the drawings. The disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Further, the terms “a” and “an” herein do not denote a limitation of quantity, but rather denote the presence of at least one of the referenced item.

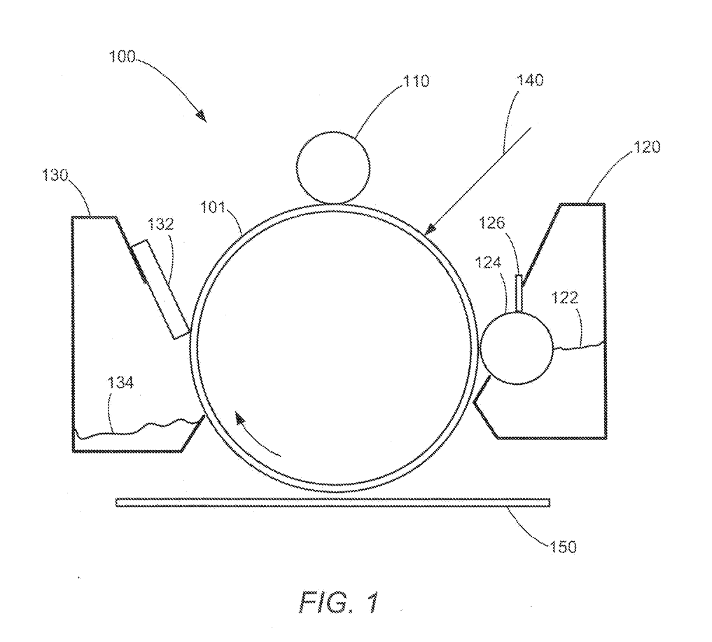

FIG. 1 illustrates a schematic representation of an example electrophotographic image forming device 100. Image forming device 100 includes a photoconductor drum 101, a charge roll 110, a developer unit 120, and a cleaner unit 130. The electrophotographic printing process is well known in the art and, therefore, is described briefly herein. During a print operation, charge roll 110 charges the surface of photoconductor drum 101. The charged surface of photoconductor drum 101 is then selectively exposed to a laser light source 140 to form an electrostatic latent image on photoconductor drum 101 corresponding to the image being printed. Charged toner from developer unit 120 is picked up by the latent image on photoconductor drum 101 creating a toned image.

Developer unit 120 includes a toner sump 122 having toner particles stored therein and a developer roll 124 that supplies toner from toner sump 122 to photoconductor drum 101. Developer roll 124 is electrically charged and electrostatically attracts the toner particles from toner sump 122. A doctor blade 126 disposed along developer roll 124 provides a substantially uniform layer of toner on developer roll 124 for subsequent transfer to photoconductor drum 101. As developer roll 124 and photoconductor drum 101 rotate, toner particles are electrostatically transferred from developer roll 124 to the latent image on photoconductor drum 101 forming a toned image on the surface of photoconductor drum 101. In one embodiment, developer roll 124 and photoconductor drum 101 rotate in the same rotational direction such that their adjacent surfaces move in opposite directions to facilitate the transfer of toner from developer roll 124 to photoconductor drum 101. A toner adder roll (not shown) may also be provided to supply toner from toner sump 122 to developer roll 124. Further, one or more agitators (not shown) may be provided in toner sump 122 to distribute the toner therein and to break up any clumped toner.

The toned image is then transferred from photoconductor drum 101 to print media 150 (e.g., paper) either directly by photoconductor drum 101 or indirectly by an intermediate transfer member. A fusing unit (not shown) fuses the toner to print media 150. A cleaning blade 132 (or cleaning roll) of cleaner unit 130 removes any residual toner adhering to photoconductor drum 101 after the toner is transferred to print media 150. Waste toner from cleaning blade 132 is held in a waste toner sump 134 in cleaning unit 130. The cleaned surface of photoconductor drum 101 is then ready to be charged again and exposed to laser light source 140 to continue the printing cycle.

The components of image forming device 100 are replaceable as desired. For example, in one embodiment, developer unit 120 is housed in a replaceable unit with photoconductor drum 101, cleaner unit 130 and the main toner supply of image forming device 100. In another embodiment, developer unit 120 is provided with photoconductor drum 101 and cleaner unit 130 in a first replaceable unit while the main toner supply of image forming device 100 is housed in a second replaceable unit. In another embodiment, developer unit 120 is provided with the main toner supply of image forming device 100 in a first replaceable unit and photoconductor drum 101 and cleaner unit 130 are provided in a second replaceable unit. Further, any other combination of replaceable units may be used as desired. In some example embodiment, the photoconductor drum 101 may not be replaced and is a permanent component of the image forming device 100.

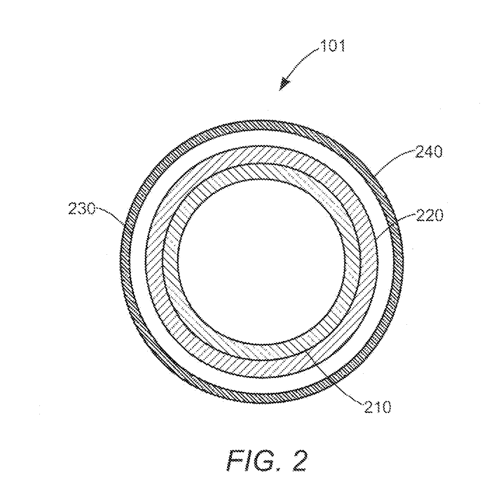

FIG. 2 illustrates an example photoconductor drum 101 in more detail. In this example embodiment, the photoconductor drum 101 is an organic photoconductor drum and includes a support element 210, a charge generation layer 220 disposed over the support element 210, a charge transport layer 230 disposed over the charge generation layer 220, and a protective overcoat layer 240 formed as an outermost layer of the photoconductor drum 101. Additional layers may be included between the support element 210, the charge generation layer 220 and the charge transport layer 230, including adhesive and/or coating layers.

The support element 210 as illustrated in FIG. 2 is generally cylindrical. However the support element 210 may assume other shapes or may be formed into a belt. In one example embodiment, the support element 210 may be formed from a conductive material, such as aluminum, iron, copper, gold, silver, etc. as well as alloys thereof. The surfaces of the support element 210 may be treated, such as by anodizing and/or sealing. In some example embodiment, the support element 210 may be formed from a polymeric material and coated with a conductive coating.

The charge generation layer 220 is designed for the photogeneration of charge carriers. The charge generation layer 220 may include a binder and a charge generation compound. The charge generation compound may be understood as any compound that may generate a charge carrier in response to light. In one example embodiment, the charge generation compound may comprise a pigment being dispersed evenly in one or more types of binders.

The charge transport layer 230 is designed to transport the generated charges. The charge transport layer 230 may include a binder and a crosslinkable hole transport molecule or a combination of a crosslinkable hole transport molecule compound and a crosslinkable binder. The crosslinkable hole transport molecule may be understood as any compound that 1) contributes to surface charge retention in the dark, 2) possesses radical crosslinkable functionality and, 3) provides a medium for hole transport upon exposure to light. In one example embodiment, the crosslinkable hole transport molecule may include organic materials capable of accepting and transporting charges.

In an example embodiment, the charge generation layer 220 and the charge transport layer 230 are configured to combine in a single layer. In such configuration, the charge generation compound and charge transport compound are mixed in a single layer.

The overcoat layer 240 is designed to protect the photoconductor drum 101 from wear and abrasion without altering the electrophotographic properties, thus extending the service life of the photoconductor drum 101. The overcoat layer 240 has a thickness of about 0.1 μm to about 10 μm. Specifically, the overcoat layer 240 has a thickness of about 1 μm to about 6 μm, and more specifically a thickness of about 3 μm to about 5 μm. The thickness of the overcoat layer 240 is kept at a range that will not provide adverse effect to the electrophotographic properties of the photoconductor drum 101.

The overcoat layer 240 is formulated from the cured, or substantially crosslinked, product of a crosslinkable hole transport molecule containing four radical polymerizable functional groups or formulated from the cured, or substantially crosslinked, product of a crosslinkable hole transport molecule containing four radical polymerizable functional groups and a crosslinkable urethane acrylate binder. The overcoat layer may further comprise an optional non-crosslinkable additive such as a surfactant.

The terms “crosslinkable” and “radical polymerizable,” and derivatives thereof, may be used interchangeably. “Cured” herein refers to, for example, a state in which the crosslinkable hole transport molecule containing four radical polymerizable groups and the crosslinkable urethane acrylate binder in the coating solution form a crosslinked or substantially crosslinked product. “Substantially crosslinked” in embodiments refers to, for example, a state in which about 60% to 100% of the hole transport compounds in the overcoat composition, for example about 70% to 100% or about 80% to 100%, are covalently bound in the composition. Curing in the present invention occurs by exposing the curable composition to ionizing electromagnetic radiation of suitable wavelength, or by exposure to an electron beam. Crosslinking of the reactive components occurs following application of the overcoat coating composition to the photoconductor.

In an example embodiment, the overcoat layer 240 includes a three-dimensional crosslinked structure formed from a curable composition. The curable composition includes a crosslinkable urethane acrylate binder having at least six radical polymerizable functional groups, and a crosslinkable hole transport molecule having four radical polymerizable functional groups. The general structure of this tetrafunctional crosslinkable hole transport molecule containing four radical polymerizable functional groups is exemplified below:

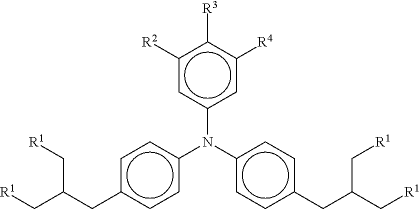

wherein R¹ is a radical polymerizable functional group selected from the group consisting of acrylate group, methacrylate group, allylic group, glycidyl ether group and epoxy group. The groups R², R³, and R⁴ may be the same or different, and wherein each of R², R³, and R⁴ are independently selected from the group consisting of (i) hydrogen, (ii) an alkyl group, which can be linear or branched, saturated or unsaturated, cyclic oracyclic, substituted or unsubstituted alkyl, (iii) an aryl group, which can be substituted or unsubstituted aryl, (iv) an arylalkyl group, which can be substituted or unsubstituted arylalkyl, wherein the alkyl portion of the arylalkyl can be linear or branched, saturated or unsaturated, cyclic or acyclic, and substituted or unsubstituted, (v) an alkylaryl group, which can be substituted or unsubstituted alkylaryl, wherein the alkyl portion of the alkylaryl can be linear or branched, saturated or unsaturated, cyclic or acyclic, and substituted or unsubstituted, (vi) an alkoxy group, (vii) an aryloxy group, which can be substituted or unsubstituted aryloxy, (viii) an arylalkyloxy group, which can be substituted or unsubstituted arylalkyloxy, wherein the alkyl portion of the arylalkyloxy can be linear or branched, saturated or unsaturated, cyclic or acyclic, and substituted or unsubstituted, and (ix) an alkylaryloxy group, which can be substituted or unsubstituted alkylaryloxy, wherein the alkyl portion of the alkylaryloxy can be linear or branched, saturated or unsaturated, cyclic or acyclic, and substituted or unsubstituted.

The radical polymerizable functional group R¹ can be any radical polymerizable functional group capable of undergoing crosslinking reactions upon exposure to light or e-beam radiation. The radical polymerizable functional group is selected from the group consisting of acrylate group, methacrylate group, allylic group, glycidyl ether group and epoxy group. In one embodiment, the radical polymerizable group R¹ is an acrylate group. In one embodiment, R² and R⁴ are hydrogen and R³ is a methyl group. The structure of the disclosed crosslinkable hole transport molecule described hereinabove wherein R¹ is an acrylate group, R² and R⁴ are hydrogen and R³ is a methyl group is exemplified below:

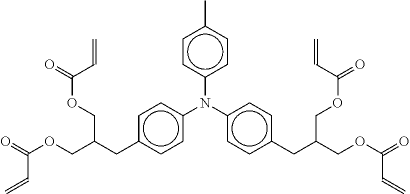

The curable overcoat composition of the present invention may also include one or more cross-linkable binders. The general purpose of the cross linkable binder is to further improve the abrasion resistance of the overcoat. The binder may also improve the adhesion of the cured overcoat to the underlying charge transport layer. In one embodiment, the crosslinkable binder is a urethane resin containing six radical polymerizable functional groups. The radical polymerizable groups may be selected from the group consisting of acrylate group, methacrylate group, styrenic group, allylic group, vinylic group, glycidyl ether group and epoxy group. In one embodiment, the radical polymerizable group is an acrylate. In an example embodiment, the crosslinkable binder is a urethane acrylate containing six acrylate groups of the following structure:

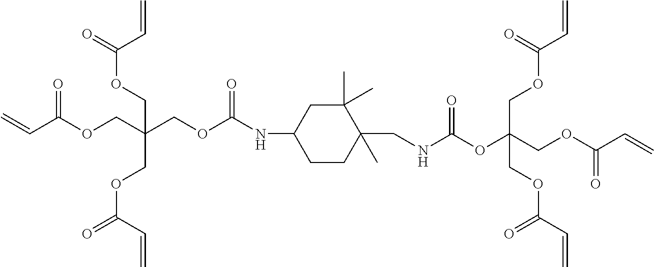 [SMILES: C=CC(=O)OCC(COC(=O)C=C)(COC(=O)C=C)COC(=O)NC1CCC(C)(CNC(=O)OC(COC(=O)C=C)(COC(=O)C=C)COC(=O)C=C)C(C)(C)C1]

and is available under the trade name EBECRYL® 8301 by Cytec Industries.

Another useful crosslinkable binder is a urethane acrylate containing 6 acrylate groups having the following structure:

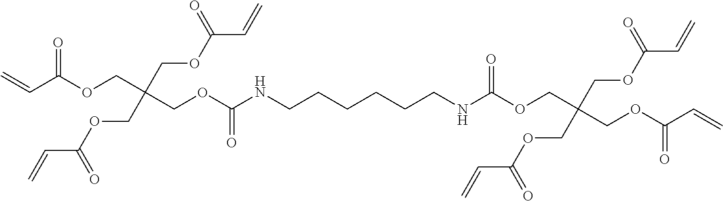 [SMILES: C=CC(=O)OCC(COC(=O)C=C)(COC(=O)C=C)COC(=O)NCCCCCCNC(=O)OCC(COC(=O)C=C)(COC(=O)C=C)COC(=O)C=C]

and is available under the trade name CN968® by Sartomer Co. The synthesis of urethane acrylates generally involves the reaction of a diisocyanate with pentaerythritol triacrylate in the presence of a catalyst. The inventors of the present invention have discovered that the choice of isocyanate and/or hydroxy acrylate plays a large role in determining the mechanical and thermal properties of the radically cured material. Curing of urethane acrylates creates a 3-dimensionally crosslinked structure. Increasing the crosslink density of the radically cured material is one way to improve the mechanical toughness and thermal properties of the materials. Urethane resins containing six or more acrylate groups are preferred cross linkable binders than binders having less than six acrylate groups. The crosslinked 3-dimensional network should be homogeneous throughout the cured material, since this improves mechanical and thermal properties. Homogeneous crosslinking is also important for applications requiring a high degree of optical transparency. Incorporation of the crosslinkable urethane acrylate binder containing six acrylate groups in the overcoat formulation allows for the combination of excellent electrostatic properties and high abrasion resistance.

The curable overcoat composition includes a unique crosslinkable hole transport molecule containing four radical polymerizable functional groups and a crosslinkable urethane acrylate resin binder containing at least six radical polymerizable functional groups. The inventors have discovered that this particular combination provides both the necessary charge transporting properties with the needed abrasion resistance. In an electrophotographic printer, such as a laser printer, an electrostatic image is created by illuminating a portion of the photoconductor surface in an image-wise manner. The wavelength of light used for this illumination is most typically matched to the absorption max of a charge generation material, such as titanylphthalocyanine. Absorption of light results in creation of an electron-hole pair. Under the influence of a strong electrical field, the electron and hole (radical cation) dissociate and migrate in a field-directed manner. Photoconductors operating in a negative charging manner move holes to the surface and electrons to ground. The holes discharge the photoconductor surface, thus leading to creation of the latent image. Cured overcoats comprising a crosslinkable hole transport molecule containing four radical polymerizable functional groups provide electrical properties that approach those of the underlying charge transport layer 230. Combining a crosslinkable hole transport molecule containing four radical polymerizable functional groups with a crosslinkable urethane acrylate binder containing six radical polymerizable groups provides an overcoat 240 with improved abrasion resistance, along with excellent electrical properties for the photoconductor drum 101.

The curable overcoat composition includes about 20 percent to about 80 percent by weight of the urethane acrylate resin binder having at least six crosslinkable functional groups, and about 20 percent to about 80 percent by weight of the crosslinkable hole transport molecule having four radical polymerizable functional groups. In one embodiment, the curable overcoat composition includes 50 percent by weight of the urethane resin having at least six radical polymerizable functional groups, and 50 percent by weight of the crosslinkable hole transport molecule having four radical polymerizable functional groups. The inventors have discovered that loading the crosslinkable urethane acrylate resin binder having at least six radical polymerizable functional groups at less than 20 percent by weight in the curable overcoat composition will not provide sufficient crosslink density to give the overcoat layer 240 sufficient abrasion resistance. Additionally, loading the crosslinkable urethane resin binder at greater than 80 percent by weight in the curable overcoat composition will not provide the overcoat layer 240 with sufficient hole mobility to give sufficient electrical properties for excellent image quality.

Ultimately the overcoat formulation of the present invention leads to a photoconductor drum having an ‘ultra long life’, thereby allowing a consumer to successfully print approximately 250,000 pages on their printer before they have to go purchase a replacement photoconductor drum.

Overcoat delamination or poor adhesion from the photoconductor surface has been noted as a problem in the prior art. Overcoat layers are typically coated in solvent systems designed to solubilize components of the overcoat formulation, while minimizing dissolution of the underlying photoconductor structure. Dissolution of components comprising the underlying photoconductor results in materials with no radical polymerizable functionality entering the overcoat layer. The result is dramatically lower crosslinking density and lower abrasion resistance since the properties of the overcoat layer are optimized by an uninterrupted 3-dimensional network. Ideally, the overcoat layer is distinct from the underlying photoconductor surface. However, the interface between the overcoat and the photoconductor surface often lacks the chemical interactions required for strong adhesion. The overcoats of the present invention have excellent adhesion to the photoconductor surface throughout the print life of the photoconductor.

The overcoat must also be optically transparent. Illumination of the photoconductor in an image-wise manner requires that layers not involved in the charge generation process be transparent to the incident light. Additionally, optical transparency is desired and indicates material and crosslink homogeneity within the overcoat structure. The overcoats of the present invention have a high degree of optical transparency throughout the print life of the photoconductor.

The overcoat must also be crack free. UV or electron beam cured films often exhibit cracks as a result of unrelieved internal stress. These cracks will manifest immediately in print, and will dramatically decrease the functional life of the overcoat. The overcoats of the present invention are crack free throughout the print life of the photoconductor.

The curable overcoat composition may further include a monomer or oligomer having at the most five radical polymerizable functional groups. The radical polymerizable functional groups of the monomer or oligomer may be selected from the group consisting of acrylate group, methacrylate group, styrenic group, allylic group, vinylic group, glycidyl ether group, epoxy group, or combinations thereof.

Suitable examples of mono-functional monomer or oligomer include, but are not limited to, methyl acrylate, methyl methacrylate, ethyl acrylate, ethyl methacrylate, propyl acrylate, propyl methacrylate, isobornyl acrylate, isobornyl methacrylate, 2-phenoxyethyl acrylate, and lauryl methacrylate.

Suitable examples of di-functional monomer or oligomer include, but are not limited to, diacrylates and dimethacrylates, comprising 1,4-butanediol diacrylate, 1,4-butanediol dimethacrylate, ethylene glycol dimethacrylate, diethylene glycol diacrylate, diethylene glycol dimethacrylate, triethylene glycol diacrylate, triethylene glycol dimethacrylate, 1,3-butylene glycol diacrylate, 1,6-hexanediol diacrylate, 1,6-hexanediol dimethacrylate, 1,12-dodecanediol methacrylate, tripropylene glycol diacrylate, 1,3-butylene glycol dimethacrylate, 1,3-butylene glycol dimethacrylate, cyclohexane dimethanol diacrylate esters, or cyclohexane dimethanol dimethacrylate esters.

Suitable examples of tri-functional monomer or oligomer include, but are not limited to, trimethylolpropane triacrylate, trimethylolpropane trimethacrylate, hydroxypropyl acrylate-modified trimethylolpropane triacrylate, ethylene oxide-modified trimethylolpropane triacrylate, propylene oxide-modified trimethylolpropane triacrylate, and caprolactone-modified trimethylolpropane triacrylate. More specifically, the tri-functional monomer or oligomer includes propoxylated (3) trimethylolpropane triacrylate, ethoxylated (6) trimethylolpropane triacrylate, propoxylated (6) trimethylolpropane triacrylate, and ethoxylated (9) trimethylolpropane triacrylate.

Suitable examples of monomers or oligomers having four radical polymerizable functional groups include, but are not limited to, pentaerythritol tetraacrylate, di-trimethylolpropane tetraacrylate, and ethoxylated pentaerythritol tetraacrylate.

Suitable examples of monomers or oligomers having five radical polymerizable functional groups include, but are not limited to, pentaacrylate esters and dipentaerythritol pentaacrylate esters.

The curable overcoat composition may further include a coating additive such as a surfactant at an amount equal to or less than about 10 percent by weight of the curable composition. Suitable examples of a coating additive include silicone derivatives like Dow Corning DC401LS and Momentive Coatsil 3509. More specifically, the amount of coating additive is about 0.05 to about 5 percent by weight, preferably about 0.01 to about 0.5 percent by weight of the curable composition. The coating additive improves the coating uniformity of the curable overcoat composition.

The curable overcoat composition is prepared by mixing the crosslinkable charge hole transport molecule containing four radical polymerizable groups and the crosslinkable urethane acrylate binder in a solvent. The curable overcoat composition is prepared, coated over the outer surface of a photoconductor drum surface and cured in the following manner. (1) Mixing a crosslinkable urethane acrylate resin binder containing at least six radical polymerizable functional groups in a solvent to form a binder solution. The solvent may include organic solvents such as tetrahydrofuran (THF), toluene, alkanes such as hexane, butanone, cyclohexanone and alcohols. The solvent may include a mixture of two or more organic solvents. The solvent system is chosen to solubilize all components of the curable overcoat composition. The mixing method may be any method that facilitates dissolution of the crosslinkable urethane acrylate binder containing at least six radical polymerizable functional groups, as well as all other components of the curable overcoat composition, into the solvent. These methods include, but are not limited to magnetic stirring, overhead stirring, roller mills or ball mills. (2) Mixing a crosslinkable hole transport molecule containing four radical polymerizable functional groups having the following general structure:

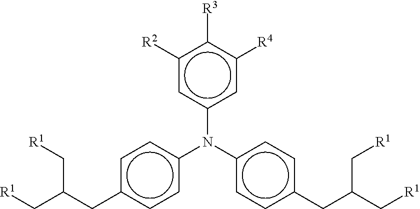

wherein R¹ is a radical polymerizable functional group selected from the group consisting of acrylate group, methacrylate group, allylic group, glycidyl ether group and epoxy group. The groups R², R³, and R⁴ may be the same or different, and wherein each of R², R³, and R⁴ are independently selected from the group consisting of (i) hydrogen, (ii) an alkyl group, which can be linear or branched, saturated or unsaturated, cyclic oracyclic, substituted or unsubstituted alkyl, (iii) an aryl group, which can be substituted or unsubstituted aryl, (iv) an arylalkyl group, which can be substituted or unsubstituted arylalkyl, wherein the alkyl portion of the arylalkyl can be linear or branched, saturated or unsaturated, cyclic or acyclic, and substituted or unsubstituted, (v) an alkylaryl group, which can be substituted or unsubstituted alkylaryl, wherein the alkyl portion of the alkylaryl can be linear or branched, saturated or unsaturated, cyclic or acyclic, and substituted or unsubstituted, (vi) an alkoxy group, (vii) an aryloxy group, which can be substituted or unsubstituted aryloxy, (viii) an arylalkyloxy group, which can be or unsubstituted arylalkyloxy, wherein the alkyl portion of the arylalkyloxy can be linear or branched, saturated or unsaturated, cyclic or acyclic, and substituted or unsubstituted, and (ix) an alkylaryloxy group, which can be substituted or unsubstituted alkylaryloxy, wherein the alkyl portion of the alkylaryloxy can be linear or branched, saturated or unsaturated, cyclic or acyclic, and substituted or unsubstituted with the -binder solution to form a curable photoconductor overcoat composition. An optional coating additive can be mixed with the above described curable photoconductor overcoat composition. An optional photoinitiator can be mixed with the above described curable photoconductor overcoat composition. An optional crosslinkable monomer or oligomer containing less than 6 radical polymerizable groups can also be mixed with this curable photoconductor overcoat composition. The chosen mixing method of these optional components with the curable photoconductor overcoat composition must facilitate the dissolution of these components into the composition.

The curable overcoat composition is then coated on the outermost surface of the photoconductor drum 101 through dipping or spraying. If the curable overcoat composition is applied through dip coating, an alcohol is used as the solvent to minimize dissolution of the components of the charge transport layer 230. The alcohol solvent includes isopropanol, methanol, ethanol, butanol, or combinations thereof.

The coated overcoat curable composition is then exposed to a radiation source of sufficient energy to induce formation of free radicals to initiate the crosslinking reaction. The exposed composition is then post-baked to anneal and relieve stresses in the coating. The radiation source of sufficient energy to induce formation of free radicals is either a UV source, or an electron beam source. If a UV source is used to generate free radicals, the curable composition may contain a photoinitiator.

Specific examples of photo initiators for use under UV cure conditions include acetone or ketal photo polymerization initiators such as diethoxyacetophenone, 2,2-dimethoxy-1,2-diphenylethane-1-one, 1-hydroxy-cyclohexyl-phenyl-ketone, 4-(2-hydroxyethoxy)phenyl-(2-hydroxy-2-propyl)ketone, 2-benzyl-2-dimethylamino-1-(4-morpholinophenyl)butanone-1,2-hydroxy-2-methyl-1-phenylpropane-1-one and 1-phenyl-1,2-propanedion-2-(o-ethoxycarbonyl)oxime; benzoinether photo polymerization initiators such as benzoin, benzoinmethylether, benzoinethylether, benzoinisobutylether and benzoinisopropylether; benzophenone photo polymerization initiators such as benzophenone, 4-hydroxybenzophenone, o-benzoylmethylbenzoate, 2-benzoylnaphthalene, 4-benzoylviphenyl, 4-benzoylphenylether, acrylated benzophenone and 1,4-benzoylbenzene; thioxanthone photo polymerization initiators such as 2-isopropylthioxanthone, 2-chlorothioxanthone, 2,4-dimethylthioxanthone, 2,4-diethylthioxanthone and 2,4-dichlorothioxanthone; phenylglyoxylate photoinitiators such as methylbenzoylformate and other photo polymerization initiators such as ethylanthraquinone, 2,4,6-trimethylbenzoyldiphenylphosphineoxide, 2,4,6-trimethylbenzoyldiphenylethoxyphosphineoxide, bis(2,4,6-trimethylbenzoyl)phenylphosphineoxide, bis(2,4-dimethoxybenzoyl)-2,4,4-trimethylpentylphosphineoxide, methylphenylglyoxyester, 9,10-phenanthrene, acridine compounds, triazine compounds and imidazole compounds. Further, a material having a photo polymerizing effect can be used alone or in combination with the above-mentioned photo polymerization initiators. Specific examples of the materials include triethanolamine, methyldiethanol amine, 4-dimethylaminoethylbenzoate, 4-dimethylaminoisoamylbenzoate, ethyl(2-dimethylamino)benzoate and 4,4-dimethylaminobenzophenone. These polymerization initiators can be used alone or in combination. The loading of photoinitiator is between about 0.5 to about 20 parts by weight and more specifically from about 2 to about 10 parts by weight per 100 parts by weight of the curable composition. A useful photoinitiator is available from the Ciba Specialty Chemicals under the tradename Darocure MBF.

Curing the composition by electron beam does not require the presence of a photoinitiator and thus may result in greater crosslink density. In one embodiment, the radiation source of sufficient energy to induce formation of free radicals is electron beam.

Synthesis of the Novel Crosslinkable Hole Transport Molecule Having Four Radical Polymerizable Groups

The general synthetic scheme for the synthesis of a novel crosslinkable hole transport molecule having tetrafunctionality involves performing the following steps:
(1) a Buchwald-Hartwig amination reaction of an aryl halide having a protected aldehyde with a primary arylamine in the presence of a base, palladium precursor, ligand and solvent to form a triarylamine having two protected aldehyde groups.
(2) a deprotection of the triarylamine having two protected aldehyde groups to form a triarylamine dialdehyde;
(3) a condensation of the triarylamine dialdehyde with a dialkylmalonate to form a triarylamine tetraester;
(4) a reduction of the triarylamine tetraester to form a triarylamine tetraol; and
(5) an introduction of crosslinking functionality to the triarylamine tetraol to form a tetrafunctional triarylamine. In an embodiment, the introduction of crosslinking functionality is done by acrylation.

The general synthesis of the novel crosslinkable hole transport molecule having four radical polymerizable groups described in the preceding Steps 1 through 5 is also set forth in the following equations:

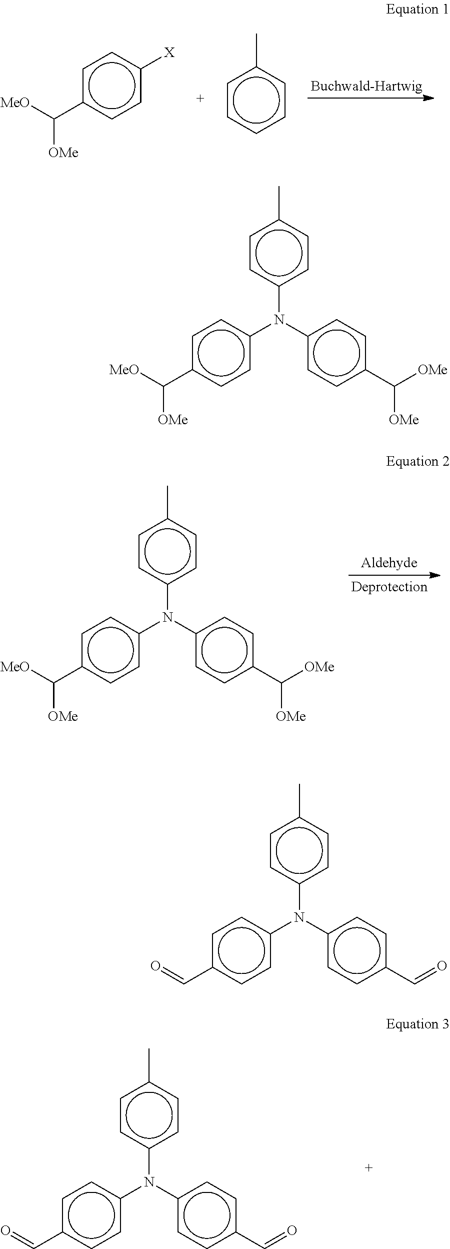

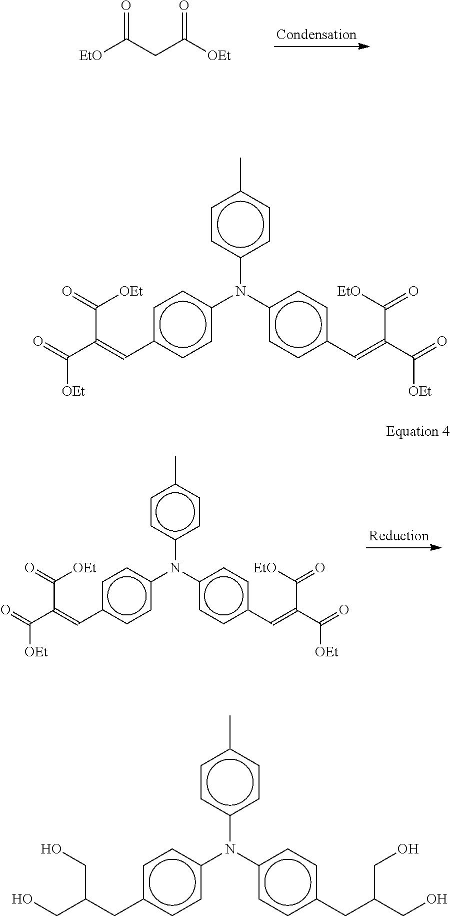

The following paragraphs set forth a detailed explanation of the synthesis of the novel crosslinkable hole transport molecule having tetrafunctionality.

Step 1 is a Buchwald-Hartwig amination reaction of an aryl halide having a protected aldehyde group with a primary arylamine in the presence of a base, palladium precursor, ligand and solvent. The novel synthesis of the crosslinkable hole transport molecule incorporates a protected aldehyde group because the conditions of the Buchwald-Hartwig reaction may lead to an undesirable Schiff base reaction between the primary arylamine and an unprotected aldehyde group.

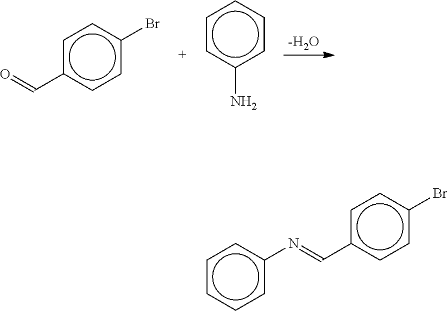

The aryl halide may be an aryl chloride, aryl bromide or aryl iodide. In an embodiment, the aryl halide is an aryl bromide.

As outlined above, the aryl halide has a protected aldehyde group. Regiochemically, the aldehyde protecting group can be substituted in the para position, the meta position or any combination thereof. In an embodiment, the aldehyde protecting group is in the para position relative to the halide of the aryl halide. In another embodiment the aldehyde protecting group is in the meta position relative to the halide of the aryl halide. The aldehyde protecting group used must be stable under the basic conditions of the Buchwald-Hartwig reaction performed in Step 1. Examples of useful aldehyde protection groups include, but are not limited to cyclic acetals, acyclic dialkyl acetals, 1, 3 dithianes, 1,3 dithiolanes, thioacetals, thioketals, and oximes. In an embodiment, the aldehyde protecting group is a dialkyl acetal such as dimethylacetal.

The primary arylamine used in the Buchwald-Hartwig reaction of Step 1 may be substituted in the para position, the meta positions or any combination thereof. The substituents in the meta and para positions are independently selected from the group consisting of (i) hydrogen, (ii) an alkyl group, which can be linear or branched, saturated or unsaturated, cyclic or acyclic, substituted or unsubstituted alkyl, (iii) an aryl group, which can be substituted or unsubstituted aryl, (iv) an arylalkyl group, which can be substituted or unsubstituted arylalkyl, wherein the alkyl portion of the arylalkyl can be linear or branched, saturated or unsaturated, cyclic or acyclic, and substituted or unsubstituted, (v) an alkylaryl group, which can be substituted or unsubstituted alkylaryl, wherein the alkyl portion of the alkylaryl can be linear or branched, saturated or unsaturated, cyclic or acyclic, and substituted or unsubstituted, (vi) an alkoxy group, (vii) an aryloxy group, which can be substituted or unsubstituted aryloxy, (viii) an arylalkyloxy group, which can be substituted or unsubstituted arylalkyloxy, wherein the alkyl portion of the arylalkyloxy can be linear or branched, saturated or unsaturated, cyclic or acyclic, and substituted or unsubstituted; and (ix) an alkylaryloxy group, which can be substituted or unsubstituted alkylaryloxy, wherein the alkyl portion of the alkylaryloxy can be linear or branched, saturated or unsaturated, cyclic or acyclic, and substituted or unsubstituted. In an embodiment, the primary arylamine is substituted with hydrogen atoms in the meta positions, and an alkyl group such as a methyl group in the para position.

The base used in the Buchwald-Hartwig reaction of Step 1 may be any base capable of removing a proton from a primary or a secondary arylamine. Examples of bases include, but are not limited to tert-BuOK, tert-BuONa, Cs₂CO₃, lithium bis(trialkylsilyl)amide, KOH, NaOH, NaOMe, K₂CO₃ or K₃PO₄. Those skilled in the art will understand that the bases exemplified above may be used alone or in combination. In an embodiment, the base is tert-BuONa.

The palladium precursor used in the Buchwald-Hartwig reaction of Step 1 is any source of palladium capable of catalyzing the Buchwald-Hartwig reaction in the presence of the appropriate ligand. The palladium precursor should have an oxidation state of 0, (Pd(0)), or be capable of being reduced to Pd(0) under the reaction conditions. In the event that the palladium precursor is not Pd(0), but rather, for example, Pd(II), addition of a small amount of a reducing agent may be required to generate the Pd (0). Suitable reducing agents include, but are not limited to tertiary amines or boronic acids. Addition of small amounts of reducing agent(s) required to reduce Pd(II) to Pd(0) are regarded as falling within the scope of the present invention. Examples of Pd(0) sources include, but are not limited to tris(dibenzylideneacetone)dipalladium (Pd₂(dba)₃), and bis(dibenzylideneacetone)palladium (Pd(dba)₂). Sources of Pd(II) include, but are not limited to palladium chloride, palladium bromide, palladium iodide, palladium acetate, palladium acetylacetonate, palladium hexafluoroacetylacetonate, palladium trifluoroacetate, allyl palladium chloride dimer, (2,2′-bipyridine)dichloropalladium, bis(benzonitrile)dichloropalladium, bis(acetonitrile)dichloropalladium, (bicyclo[2.2.1]hepta-2,5-diene)dichloropalladium, dichloro(1,5-cyclooctadiene)palladium, di bromobis(triphenylphosphine)palladium, dichloro(N,N,N′,N′-tetramethylethylenediamine)palladium, dichloro(1,10-phenanthroline)palladium, dichlorobis(triphenylphosphinepalladium), ammonium tetrachloropalladate, diaminedibromopalladium, diaminedichloropalladium, diaminediiodopalladium, potassium tetrabromopalladate, potassium tetrachloropalladate and sodium tetrachloropalladate. Those skilled in the art will understand that the palladium precursors exemplified above may be used alone or in combination. In an embodiment, the palladium precursor is tris(dibenzylideneacetone)dipalladium.

The ligand used in the Buchwald-Hartwig reaction of Step 1 is any molecule capable of coordinating to the palladium precursor and facilitating the Buchwald-Hartwig reaction. These ligands include, but are not limited to dialkylbiarylphosphines, ferrocenyl diphenyl, dialkyl phosphines and bulky, electron rich phosphines. Examples of dialkylbiarylphosphine ligands include: 2-Dicyclohexylphosphino-2′-(N,N-dimethylamino)biphenyl (DavePhos), 2-Dicyclohexylphosphino-2′,4′,6′-triisopropylbiphenyl (Xphos), 2-Dicyclohexylphosphino-2′,6′-dimethoxybiphenyl (Sphos), 2-Di-tert-butylphosphino-2′,4′,6′-triisopropylbiphenyl (tBuXPhos), (2-Biphenyl)dicyclohexylphosphine, 2-(Dicyclohexylphosphino)biphenyl (CyJohnPhos), (2-Biphenyl)di-tert-butylphosphine (JohnPhos), 2-Dicyclohexylphosphino-2′,6′-diisopropoxybiphenyl (RuPhos), 2-Di-tert-butylphosphino-2′-methylbiphenyl (tBuMePhos), 2-Di-tert-butylphosphino-3,4,5,6-tetramethyl-2′,4′,6′-triisopropyl-1,1′-biphenyl 2-Di-tert-butylphosphino-2′-methylbiphenyl (tBuMePhos), 2-Di-tert-butylphosphino-3,4,5,6-tetramethyl-2′,4′,6′-triisopropyl-1,1′-biphenyl (Tetramethyl tBuXPhos), and 2-(Dicyclohexylphosphino)3,6-dimethoxy-2′,4′,6′-triisopropyl-1,1′-biphenyl (BrettPhos). Examples ferrocenyl diphenyl and dialkyl phosphines include: 1,1′-Ferrocenediyl-bis(diphenylphosphine) (dppf), 1,2,3,4,5-Pentaphenyl-1′-(di-tert-butylphosphino)ferrocene (Q-Phos), 1,1′-Bis(di-tert-butylphosphino)ferrocene, 1,1′-Bis(dicyclohexylphosphino)ferrocene and 1,1′-Bis(diisopropylphosphino)ferrocene. An example of a bulky, electron rich phosphine is tri-tert-butylphosphine. An air stable variant of the tri-tert-butylphosphine ligand is tri-tert-butylphosphonium tetrafluoroborate. Those skilled in the art will understand that the ligands exemplified above may be used alone or in combination. In an embodiment, the ligand is tri-tert-butylphosphonium tetrafluoroborate.

The solvent used in the Buchwald-Hartwig reaction of Step 1 is any non-halogenated organic solvent, so long as it is free of moisture. Halogenated solvents may react in the Buchwald-Hartwig amination and thus lower the yield of the desired product. Water molecules can also react with the aryl halide to produce aryl alcohols (phenols), thus lowering the yield of the expected product. Common organic solvents include, but are not limited to cyclic ethers such as tetrahydrofuran (THF), ethers such as diethyl ether or tert-butyl methyl ether aromatic solvents such as toluene or xylene, acetate solvents such as ethyl acetate or butyl acetate, aliphatic solvents such as hexane or decane, and amide solvents such as dimethyl formamide (DMF), dimethyl acetamide (DMAc) and N-methylpyrrolidone (NMP). Those skilled in the art will understand that the solvents exemplified above may be used alone or in combination. In an embodiment, the solvent is toluene.

Step 2 is the deprotection of the resulting triarylamine having two protected aldehyde groups formed in Step 1 to form a triarylamine dialdehyde. The aldehyde deprotecting agent is used to generate the triarylamine dialdehyde upon completion of the Buchwald-Hartwig reaction described in Step 1. The choice of aldehyde deprotecting agent will depend upon the aldehyde protecting group chosen. Examples of aldehyde deprotecting agents include, but are not limited to aqueous strong acids such as aqueous HCl and aqueous HBr, and Lewis acids such as Er(OTf)₃ and CuCl₂. Those skilled in the art will understand that the aldehyde deprotecting agents exemplified above may be used alone or in combination. In an embodiment, the aldehyde deprotecting agent is aqueous HCl.

Step 3 is the condensation of the resulting triarylamine dialdehyde formed in Step 2 with a dialkylmalonate to form a triarylamine tetraester. This condensation reaction may be a Knoevenagel condensation type reaction. This condensation reaction may be performed in the presence of heat, catalyst and a solvent. Typical catalysts include organic bases such as piperdine, organic acids such as acetic acid, 1:1 mixtures of organic bases and organic acids, and Lewis acids. Those skilled in the art will understand that the catalysts exemplified above may be used alone or in combination. In an embodiment, the catalyst is piperdine. The dialkylmalonate is a dialkylmalonate that can participate in a Knoevenagel condensation reaction and form a triarylamine tetraester. Examples of useful dialkylmalonates include but are not limited to dimethylmalonate, diethylmalonate, dipropylmalonate and dibutylmalonate. In an embodiment, the dialkylmalonate is diethylmalonate.

The solvent used is a solvent suitable for Knoevenagel reactions. Suitable organic solvents include, but are not limited to toluene, xylene, benzene, cyclic alkanes such as cyclohexane, acyclic alkanes such as hexane or decane, water and alcohol solvents such as ethanol, propanol and butanol. Those skilled in the art will understand that the solvents exemplified above may be used alone or in combination. If an organic solvent is chosen, the water byproduct may be removed during the reaction. Suitable means of removing water include, but are not limited to molecular sieves and Dean-Stark trap. In an embodiment, the solvent is cyclohexane and the means of removing water is a Dean-Stark trap.

Step 4 is the reduction of the resulting triarylamine tetraester formed in Step 3 to form a triarylamine tetraol. The reduction may be performed using a reagent that reduces esters and α, β-unsaturated carbonyls to primary alcohols. The reduction may be performed in the presence of a reducing agent and a solvent. The reduction may also include a dialkylamine. Suitable reducing agents include, but are not limited to LiALH₄, DIBAL, LiBH₄, LiCl/NaBH₄, and NaBH₄ in the presence of a Lewis acid. Suitable Lewis acids include, but are not limited to CoCl₂, CaCl₂, CuCl₂ and ZnCl₂. Those skilled in the art will understand that the reducing agents and Lewis acids exemplified above may be used alone or in combination. Suitable dialkylamines include diethylamine, dipropylamine and diisopropylamine. In an example, the reducing agent is NaBH₄, the Lewis acid is CoCl₂ and the dialkylamine is diisopropylamine.

The solvent used in the reduction reaction described in Step 4 is a solvent suitable for an ester α, β-unsaturated carbonyl reduction. Choice of a solvent or mixture of solvents may depend upon the reducing agents chosen for the reduction reaction. Suitable solvents include, but are not limited to ethanol, THF, diethyl ether, dichloromethane, toluene or water. Those skilled in the art will understand that the solvents exemplified above may be used alone or in combination. In an embodiment, the solvent is a mixture of THF and ethanol.

Step 5 is acrylation of the resulting triarylamine tetraol formed in Step 4 to form a triarylamine tetraacrylate. This acrylation is a reaction method resulting in the formation of an acrylate from a primary alcohol. A method of acrylation may involve the reaction of a primary alcohol with acryloyl chloride in the presence of solvent and a base, although other acrylation methods may be used. Useful organic solvents include, but are not limited to cyclic ethers such as tetrahydrofuran (THF) or methyl tetrahydrofuran, ethers such as diethyl ether or tert-butyl methyl ether, halogenated solvents such as dichloromethane, aromatic solvents such as toluene or xylene, acetate solvents such as ethyl acetate or butyl acetate, aliphatic solvents such as hexane or decane, and amide solvents such as dimethyl formamide (DMF), dimethyl acetamide (DMAc) and N-methylpyrrolidone (NMP). Those skilled in the art will understand that the solvents listed above may be used alone or in combination. In an embodiment, the solvent is DMF. The base used in Step 5 is a base capable of activating the primary alcohol, leading to formation of the acrylate bond. Useful bases include, but are not limited to triethylamine, tripropylamine, piperdine, dimethylamino pyridine (DMAP) and pyridine. In an embodiment, the base is triethylamine.

Synthesis of the Novel Crosslinkable Hole Transport Molecule Having Four Radical Polymerizable Groups

Buchwald-Hartwig Reaction

An oven dried 2 L 3-neck round bottom flask equipped with a Teflon-coated magnetic stirrer and a reflux condenser was charged with anhydrous toluene (600 mL), para-toluidine (30.10 g, 281 mmol), 4-bromobenzaldehyde dimethyl acetal (136.8 g, 592 mmol), sodium tert-butoxide (69.67 g, 725 mmol), tris(dibenzylideneacetone) dipalladium(0) (1.00 g, 1.09 mmol) and tri-tert-butylphosphonium tetrafluoroborate (0.660 g, 2.27 mmol). The resulting slurry was heated to reflux for 18 h. The material was cooled to room temperature and filtered. Solvent was removed under vacuum to yield the following triarylamine compound 1:

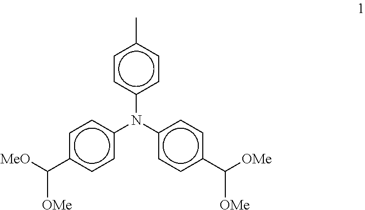

Aldehyde Deprotection

Aqueous HCl was added to triarylamine compound 1 with vigorous stirring to yield a dull yellow solid. This material was filtered, washed with water and dried under vacuum to yield 86.0 g of the following triarylamine dialdehyde compound 2:

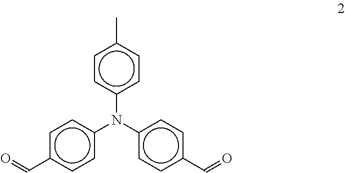

Condensation

An oven dried 250 mL 4-neck round bottom flask equipped with a Teflon-coated magnetic stirrer and a Dean-Stark trap was charged with cyclohexane (120 mL) triarylamine dialdehyde compound 2 (12.0 g, 38 mmol), diethyl malonate (15.24 g, 95 mmol), and piperidine (1.62 g, 19 mmol). The resulting solution was heated to reflux for 18 h. The resulting material was cooled to room temperature and solvent was removed under vacuum. The resulting oil was triturated with hexane (50 mL). The resulting yellow solid was washed with hexane (2×50 mL) and dried in an oven at 60° C. to yield 18.0 g of the following triarylamine tetraester compound 3:

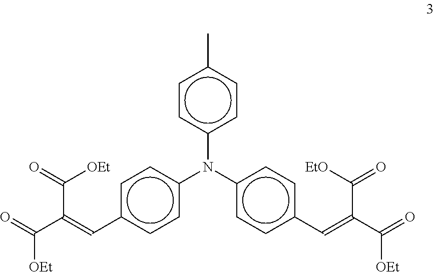

Reduction

A 1 L jacketed reaction vessel was equipped with a mechanical stirrer and a condenser was charged with THF (150 mL), triarylamine tetraester compound 3 (20.0 g, 33 mmol), anhydrous ethanol, cobalt (II) chloride hexahydrate (1.59 g, 6.7 mmol) and diisopropylamine (1.87 mL, 13 mmol). The material was cooled to 15° C. and sodium borohydride (27.7 g, 732 mmol) was added slowly over 1 h. 90 Minutes after the addition was complete, the jacket temperature was raised to 20° C. and the resulting mixture was stirred for 18 hours. The reaction was quenched with water (200 mL), then by aqueous ammonium chloride. The mixture was filtered and the solids were washed with water (1 L). The resulting aqueous layer was extracted with ethyl acetate. The organic layer was washed with aqueous HCl, aqueous KOH, brine and dried over MgSO₄. Solvent was removed under vacuum to yield 13.2 g of the following triarylamine tetraol compound 4:

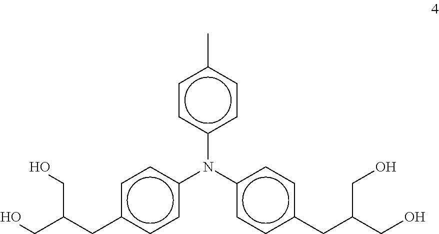

Acrylation

A 1 L 3-neck flask was equipped with a Teflon-coated magnetic stirrer and a dropping funnel was charged with triarylamine tetraol compound 4 (10.5 g, 24.1 mmol) and triethylamine (26.8 mL, 19.5 g, 193 mmol). Acryloyl chloride (19.5 mL, 21.7 g, 240 mmol) was added to the dropping funnel and then added to the mixture over 20 min. The material was stirred at room temperature for 20 h. The reaction was then quenched with aqueous sodium hydroxide and the material was transferred to a separatory funnel containing 400 mL of ethyl acetate. The ethyl acetate solution was washed with aqueous sodium hydroxide, water, saturated NaHCO₃, brine and dried over MgSO₄. Solvent was removed under vacuum and the resulting yellow oil was purified by flash chromatography. Removal of solvent provided the novel triarylamine tetraacrylate compound 5. Triarylamine tetraacrylate compound 5 was then used as the crosslinkable hole transport molecule in an overcoat layer for use in a photoconductor.

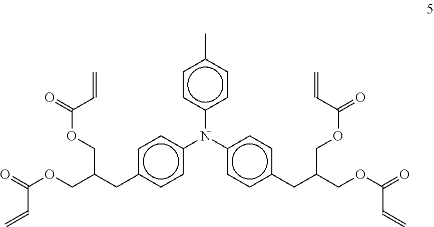

Preparation of a Photoconductor Drum to be Used in a Color Printer

A photoconductor drum to be used in a color printer (hereinafter referred to ‘Color Base PC Drum’) was formed using an aluminum substrate, a charge generation layer coated onto the aluminum substrate, and a charge transport layer coated on top of the charge generation layer.

The charge generation layer was prepared from a dispersion including type IV titanyl phthalocyanine, type I titanylphthalocyanine, polyvinylbutyral, poly(methyl-phenyl)siloxane and polyhydroxystyrene at a weight ratio of 41:21:34:1.3:2.5 in a mixture of 2-butanone and cyclohexanone solvents. The polyvinylbutyral is available from Sekisui Chemical Co., Ltd under the trade name BX-1®. The charge generation dispersion was coated onto the aluminum substrate through dip coating and dried at 100° C. for 15 minutes to form the charge generation layer having a thickness of less than 1 μm, specifically a thickness of about 0.2 μm to about 0.3 μm.

The charge transport layer was prepared from a formulation including terphenyl diamine derivatives and polycarbonate at a weight ratio of 33:67 in a mixed solvent of THF and 1,4-dioxane. The charge transport formulation was coated on top of the charge generation layer and cured at 120° C. for 1 hour to form the charge transport layer having a thickness of about 30 μm as measured by an eddy current tester.

Preparation of a Photoconductor Drum to be Used in a Monochrome Printer

A photoconductor drum to be used in a monochrome printer (hereinafter referred to ‘Monochrome Base PC Drum’) was formed using an aluminum substrate, a charge generation layer coated onto the aluminum substrate, and a charge transport layer coated on top of the charge generation layer.

The charge generation layer was prepared from a dispersion including type IV titanyl phthalocyanine, polyvinylbutyral, poly(methyl-phenyl)siloxane and polyhydroxystyrene at a weight ratio of 45:27.5:24.75:2.75 in a mixture of 2-butanone and cyclohexanone solvents. The polyvinylbutyral is available from Sekisui Chemical Co., Ltd under the trade name BX-1®. The charge generation dispersion was coated onto the aluminum substrate through dip coating and dried at 100° C. for 15 minutes to form the charge generation layer having a thickness of less than 1 μm, specifically a thickness of about 0.2 μm to about 0.3 μm.

The charge transport layer was prepared from a formulation including terphenyl diamine derivatives and polycarbonate at a weight ratio of 33:67 in a mixed solvent of THF and 1,4-dioxane.

The charge transport formulation was coated on top of the charge generation layer and cured at 120° C. for 1 h to form the charge transport layer having a thickness of about 30 μm as measured by an eddy current tester.

Preparation of Example Overcoat Layer 1

The Example Overcoat Layer 1 was prepared from a formulation including the following: (25 g) of the crosslinkable hole transport molecule containing four radical polymerizable functional groups shown below:

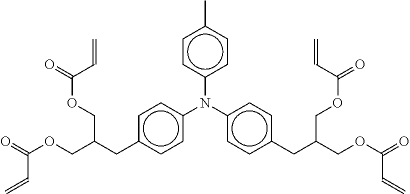

EBECRYL® 8301 (25 g), ethanol (100 g) and CoatOsil® 3509 (0.03 g). The formulation was coated through dip coating on the outer surface of the Color Base PC Drum. The coated layer was then exposed to an electron beam source at an accelerating voltage of 90 kV, a current of 3 mA, and an exposure time of 1.2 seconds. The electron beam cured photoreceptor was then thermally cured at 120° C. for 1 h. The thickness of the overcoat was determined by eddy current measurement. The resulting photoconductor is referred to as Color Photoconductor Drum #1.

Preparation of Example Overcoat Layer 2

The Example Overcoat Layer 2 was prepared from a formulation including the crosslinkable hole transport molecule containing four radical polymerizable functional groups (25 g) described in Preparation of Example Overcoat Layer 1 above, EBECRYL 8301 (25 g) and ethanol (100 g) and CoatOsil 3509 (0.03 g). The formulation was coated through dip coating on the outer surface of the Color Base PC Drum. The coated layer was then exposed to an electron beam source at an accelerating voltage of 110 kV, a current of 3 mA, and an exposure time of 1.2 seconds. The electron beam cured photoreceptor was then thermally cured at 120° C. for 1 h. The thickness of the overcoat was determined by eddy current measurement. The resulting photoconductor is referred to as Color Photoconductor Drum #2.

Preparation of Example Overcoat Layer 3

The Example Overcoat Layer 3 was prepared from a formulation including the crosslinkable hole transport molecule containing four radical polymerizable functional groups (25 g) described in Preparation of Example Overcoat Layer 1 above, EBECRYL 8301 (25 g), ethanol (100 g) and CoatOsil 3509 (0.03 g). The formulation was coated through dip coating on the outer surface of the Monochrome Base PC Drum. The coated layer was then exposed to an electron beam source at an accelerating voltage of 90 kV, a current of 3 mA, and an exposure time of 1.2 seconds. The electron beam cured photoreceptor was then thermally cured at 120° C. for 1 h. The thickness of the overcoat was determined by eddy current measurement. The resulting photoconductor is referred to as Monochrome Photoconductor Drum.

Example Comparative Color Photoconductor Drum

An overcoat layer was prepared from a formulation including a crosslinkable hole transport molecule containing two radical polymerizable functional groups (25 g) shown below:

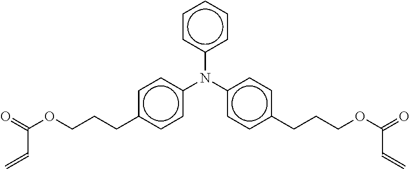

and EBECRYL 8301 (20 g), ethanol (100 g) and CoatOsil 3509 (0.03 g). The formulation was coated through dip coating on the outer surface of the Color Base PC Drum. The coated layer was then exposed to an electron beam source at an accelerating voltage of 90 kV, a current of 3 mA, and an exposure time of 1.2 seconds. The electron beam cured photoreceptor was then thermally cured at 120° C. for 1 h. The thickness of the overcoat was determined by eddy current measurement. The resulting photoconductor is referred to as Comparative Color Photoconductor Drum.

Example Comparative Monochrome Photoconductor Drum

An overcoat layer was prepared from a formulation including a crosslinkable hole transport molecule containing two radical polymerizable functional groups (25 g) shown in Example Comparative Color Photoconductor Drum, EBECRYL 8301 (20 g), ethanol (100 g) and CoatOsil 3509 (0.03 g). The formulation was coated through dip coating on the outer surface of the photoconductor drum formed in Monochrome Base PC Drum. The coated layer was then exposed to an electron beam source at an accelerating voltage of 90 kV, a current of 3 mA, and an exposure time of 1.2 seconds. The electron beam cured photoreceptor was then thermally cured at 120° C. for 1 hour. The thickness of the overcoat was determined by eddy current measurement. The resulting photoconductor is referred to as Comparative Monochrome Photoconductor Drum.

Testing Results

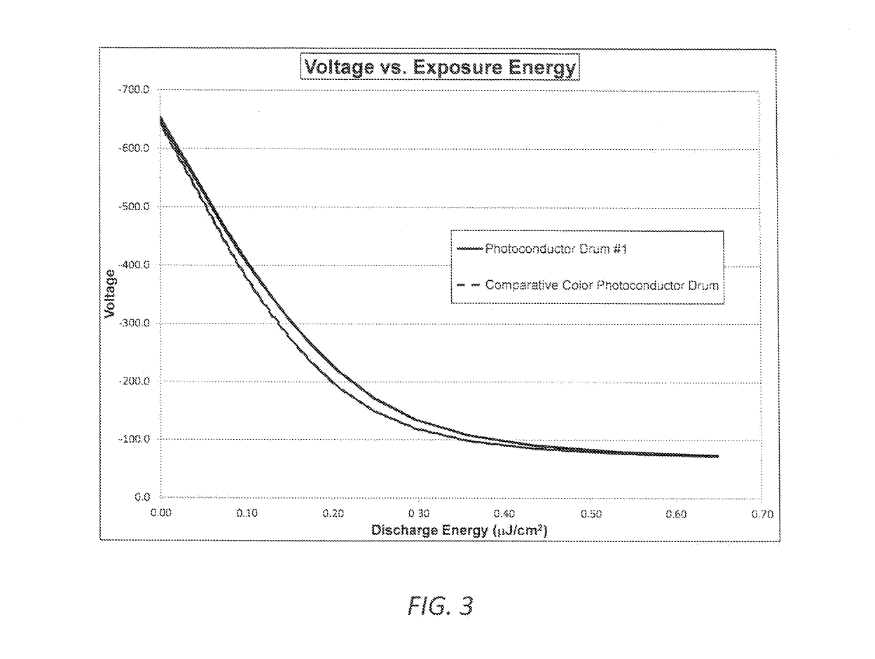

Color Photoconductor Drum #1 and Comparative Color Photoconductor Drum were analyzed on an in-house electrostatic tester. Both photoconductor drums were charged to −650 V and exposed to a 780 nm light source of variable energy. The voltage versus exposure energy curves are shown in FIG. 3. These curves show that the initial electrical properties imparted by the overcoat on Color Photoconductor Drum #1 were very similar to that for the Comparative Color Photoconductor Drum. Therefore there was no compromising of the photoconductor's electrical properties by overcoating the photoconductor drum with Example Overcoat Layer 1.

Color Photoconductor Drums #1 and #2, and Comparative Color Photoconductor Drum were installed in a Lexmark C780 Color Laser Printer. The printer was run in a 50 ppm, 2 page/pause, simplex run mode until overcoat wear thru as determined by periodic eddy current measurements. Table 1 summarizes the initial overcoat thickness, and overcoat life as expressed in 1000 (k) prints.

TABLE 1

| Example | Photoconductor Life (k prints) |
|---|---|
| Photoconductor Drum #1 | 300 |
| Photoconductor Drum #2 | 440 |
| Comparative Photoconductor Drum | 140 |

Table 1 describes the abrasion resistance of color Photoconductor Drums #1 and #2 versus Example Comparative Color Photoconductor Drum. The printing platform is a Lexmark C780 color laser printer that uses an intermediate transfer member (ITM). In this configuration, the photoconductor drum deposits the toned image to an ITM, which in turn transfers the image to paper. The wear in printers utilizing an ITM is very uniform from top-to-bottom of the photoconductor drum in this configuration. The data shows a dramatic increase in print count from the photoconductor drum of Color Photoconductor Drums #1 versus Example Comparative Color Photoconductor Drum. Color Photoconductor Drums #2 shows that an even greater increase in print count is achieved by increasing the electron beam energy from 90 kV to 110 kV.

Monochrome Photoconductor Drum and Comparative Monochrome Photoconductor Drum were installed in a Lexmark MS812 Monochrome Laser Printer. The printer was run in a 70 ppm, 4 page/pause, duplex run mode until overcoat wear thru as determined by periodic eddy current measurement. Table 2 summarizes the initial overcoat thickness, and overcoat life as expressed in ‘k’ or thousands of prints.

TABLE 2

| | Overcoat Thickness | Overcoat Life |
|---|---|---|
| Example | (μm) | (k prints) |
| Monochrome Photoconductor | 4.2 | 280 |
| Drum | | |
| Comparative Monochrome | 4.3 | 100 |
| Photoconductor Drum | | |

Table 2 describes the abrasion resistance of the photoconductor of the Monochrome Photoconductor Drum versus the Comparative Monochrome Photoconductor Drum. The printing platform is a Lexmark MS812 monochrome laser printer that does not use an ITM. In this configuration, the photoconductor drum deposits the toned image directly to the paper. The wear in direct-to-paper printer configurations is directed in the area where the paper edges meet the photoconductor. The data shows a dramatic increase in print count from Monochrome Photoconductor Drum having the inventive overcoat formulated with the crosslinkable hole transport molecule having tetrafunctionality versus the Comparative Monochrome Photoconductor Drum formulated with a hole transport molecule having only di functionality.

Without wishing to be bound by theory, the inventors believe that the increase in overcoat life derived from overcoat layers comprising crosslinkable hole transport molecules containing four radical polymerizable functional groups charge transport stems an increase in crosslink density versus a hole transport molecule containing two radical polymerizable functional groups. Increasing the number of crosslinkable functional groups per molecule increases the crosslink density of the cured overcoat, and thus increases the abrasion resistance.

The foregoing description illustrates various aspects of the present disclosure. It is not intended to be exhaustive. Rather, it is chosen to illustrate the principles of the present disclosure and its practical application to enable one of ordinary skill in the art to utilize the present disclosure, including its various modifications that naturally follow. All modifications and variations are contemplated within the scope of the present disclosure as determined by the appended claims. Relatively apparent modifications include combining one or more features of various embodiments with features of other embodiments.

What is claimed is:

1. A method of preparing a photoconductor comprising:
providing an electrically conductive substrate;
preparing a charge generation layer dispersion:
coating the charge generation layer dispersion onto the electrically conductive substrate to form a charge generation layer;
preparing a charge transport layer dispersion:
coating the charge transport layer dispersion over the charge generation layer to form a charge transport layer;
preparing an overcoat layer formulation including:
(1) a urethane acrylate resin having at least six radical polymerizable functional groups, wherein the radical polymerizable functional groups are selected from the groups consisting of acrylate, methacrylate, styrenic, allylic, vinylic, glycidyl ether, epoxy and combinations thereof;
(2) a crosslinkable hole transport molecule having four radical polymerizable functional groups having the following general formula: 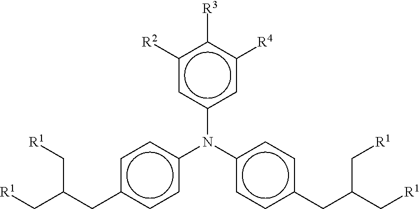
wherein R¹ is a radical polymerizable group, the groups R², R³, and R⁴ may be the same or different, and wherein each of R², R³, and R⁴ are independently selected from the group consisting of (i) hydrogen, (ii) an alkyl group, which can be linear or branched, saturated or unsaturated, cyclic or acyclic, substituted or unsubstituted alkyl, (iii) an aryl group, which can be substituted or unsubstituted aryl, (iv) an arylalkyl group, which can be substituted or unsubstituted arylalkyl, wherein the alkyl portion of the arylalkyl can be linear or branched, saturated or unsaturated, cyclic or acyclic, and substituted or unsubstituted, (v) an alkylaryl group, which can be substituted or unsubstituted alkylaryl, wherein the alkyl portion of the alkylaryl can be linear or branched, saturated or unsaturated, cyclic or acyclic, and substituted or unsubstituted, (vi) an alkoxy group, (vii) an aryloxy group, which can be substituted or unsubstituted aryloxy, (viii) an arylalkyloxy group, which can be substituted or unsubstituted arylalkyloxy, wherein the alkyl portion of the arylalkyloxy can be linear or branched, saturated or unsaturated, cyclic or acyclic, and substituted or unsubstituted, and (ix) an alkylaryloxy group, which can be substituted or unsubstituted alkylaryloxy, wherein the alkyl portion of the alkylaryloxy can be linear or branched, saturated or unsaturated, cyclic or acyclic, and substituted or unsubstituted; and
(3) an organic solvent;
coating the overcoat layer formulation over the charge transport layer; and
curing the overcoat layer formulation to form a photoconductor having an overcoat layer over the charge transport layer and the charge generation layers.

2. The method of claim 1 wherein the urethane acrylate resin having at least six radical polymerizable functional groups is a hexa-functional aromatic urethane acrylate resin having the following structure:

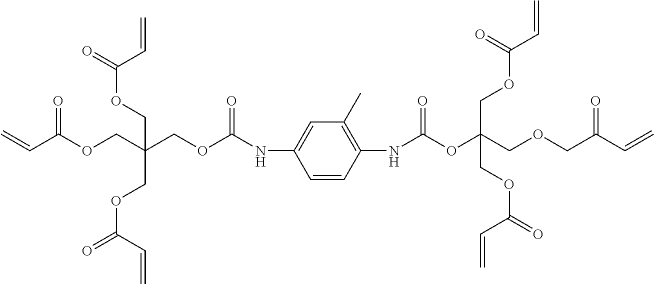 [SMILES: C=CC(=O)COCC(COC(=O)C=C)(COC(=O)C=C)OC(=O)Nc1ccc(NC(=O)OCC(COC(=O)C=C)(COC(=O)C=C)COC(=O)C=C)cc1C]

3. The method of claim 1 wherein the urethane resin having at least six radical polymerizable functional groups is a hexa-functional aliphatic urethane acrylate resin having the following structure:

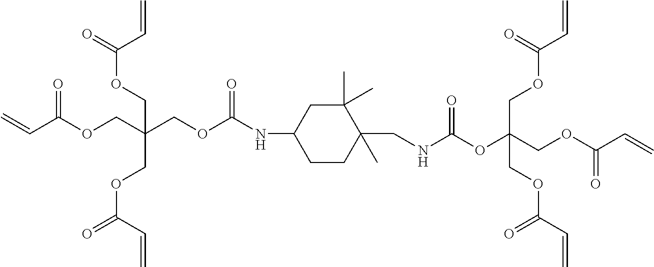 [SMILES: C=CC(=O)OCC(COC(=O)C=C)(COC(=O)C=C)COC(=O)NC1CCC(C)(CNC(=O)OC(COC(=O)C=C)(COC(=O)C=C)COC(=O)C=C)C(C)(C)C1]

4. The method of claim 1 wherein the overcoat layer is cured by an electron beam.

5. The method of claim 4 wherein the cured overcoat layer has a thickness of about 0.1 μm to about 10 μm.

6. The method of claim 1 wherein the radical polymerizable group R¹ is selected from the group consisting of an acrylate group, a methacrylate group, an allylic group, a glycidyl an ether group and an epoxy group.

7. The method of claim 6 wherein the radical polymerizable group R¹ is an acrylate group.

8. The method of claim 1 wherein R² and R⁴ are hydrogen.

9. The method of claim 1 wherein R³ is a methyl group.
